(19) United States
(12) Patent Application Publication
(10) Pub. No.: US 2023/0261639 A1
(43) Pub. Date: Aug. 17, 2023

(54) ACOUSTIC WAVE DEVICE

(71) Applicant: Murata Manufacturing Co., Ltd., Nagaokakyo-shi (JP)

(72) Inventors: Tetsuya KIMURA, Nagaokakyo-shi (JP); Shintaro KUBO, Nagaokakyo-shi (JP); Yutaka KISHIMOTO, Nagaokakyo-shi (JP); Masashi OMURA, Nagaokakyo-shi (JP); Hajime YAMADA, Nagaokakyo-shi (JP)

(21) Appl. No.: 18/136,373

(22) Filed: Apr. 19, 2023

Related U.S. Application Data
(63) Continuation of application No. PCT/JP2021/038195, filed on Oct. 15, 2021.
(60) Provisional application No. 63/104,649, filed on Oct. 23, 2020.
(60) Provisional application No. 63/168,299, filed on Mar. 31, 2021.
(60) Provisional application No. 63/195,798, filed on Jun. 2, 2021.

(51) Int. Cl. H03H 9/25; H03H 3/02; H03H 9/02; H03H 9/145; H03H 9/17

(52) U.S. Cl. CPC H03H 9/25; H03H 3/02; H03H 9/02574; H03H 9/14541; H03H 9/02559; H03H 9/173

(57) ABSTRACT

An acoustic wave device includes a support substrate, a dielectric film, a piezoelectric layer, and an excitation electrode. The piezoelectric layer includes first and second main surfaces. The second main surface is on a side including the dielectric film. A cavity portion is provided in the dielectric film and overlaps at least a portion of the excitation electrode in plan view. The dielectric film includes a side wall surface facing the cavity portion and including an inclined portion inclined so that a width of the cavity portion decreases with increasing distance away from the piezoelectric layer. The inclined portion includes at least an end portion on a side including the piezoelectric layer, in the side wall surface. When an angle between the inclined portion and the second main surface of the piezoelectric layer is defined as an inclination angle α, the inclination angle α is from about 40° to about 80° inclusive.

### CROSS REFERENCE TO RELATED APPLICATIONS

This application claims the benefit of priority to Provisional Application Nos. 63/195,798 filed on Jun. 2, 2021, 63/168,299 filed on Mar. 31, 2021, and 63/104,649 filed on Oct. 23, 2020 and is a Continuation application of PCT Application No. PCT/JP2021/038195 filed on Oct. 15, 2021. The entire contents of each application are hereby incorporated herein by reference.

### BACKGROUND OF THE INVENTION

### 1. Field of the Invention

The present invention relates to an acoustic wave device.

### 2. Description of the Related Art

Conventionally, acoustic wave devices have been widely used for filters of cellular phones, for example. Japanese Unexamined Patent Application Publication No. 2016-086308 discloses an example of a piezoelectric resonator as an acoustic wave device. In this acoustic wave device, a fixed layer is provided on a support substrate. A piezoelectric thin film is provided on the fixed layer. An inter digital transducer (IDT) is provided on the piezoelectric thin film. A gap is formed in the fixed layer on a portion which is opposed to the IDT. The gap is surrounded by a back surface of the piezoelectric thin film and an inner wall surface of the fixed layer. Dielectric such as SiO₂ is used for the fixed layer.

When a dielectric film is interposed between a support substrate and a piezoelectric layer and a cavity portion is formed in the dielectric film, cracks are sometimes generated in the dielectric film. Further, the piezoelectric layer sometimes sticks to an inner wall surface of the dielectric film. This may cause deterioration of electrical characteristics of an acoustic wave device.

### SUMMARY OF THE INVENTION

Preferred embodiments of the present invention provide acoustic wave devices that each reduce or prevent generation of cracks in a dielectric film and sticking of a piezoelectric layer to the dielectric film.

An acoustic wave device according to a preferred embodiment of the present invention includes a support substrate, a dielectric film on the support substrate, a piezoelectric layer on the dielectric film, and an excitation electrode on the piezoelectric layer. The piezoelectric layer includes a first main surface and a second main surface, which are opposed to each other. The second main surface is positioned on a side including the dielectric film. A cavity portion is provided in the dielectric film and the cavity portion overlaps with at least a portion of the excitation electrode in plan view. The dielectric film includes a side wall surface that faces the cavity portion. The side wall surface includes an inclined portion inclined so that a width of the cavity portion decreases with increasing distance away from the piezoelectric layer. The inclined portion includes at least an end portion, the end portion being on a side including the piezoelectric layer, in the side wall surface. When an angle between the inclined portion of the side wall surface and the second main surface of the piezoelectric layer is defined as an inclination angle, the inclination angle is from about 40° to about 80° inclusive.

According to preferred embodiments of the present invention, generation of cracks in a dielectric film and sticking of a piezoelectric layer to the dielectric film are reduced or prevented.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a schematic elevational cross-sectional view of an acoustic wave device according to a first preferred embodiment of the present invention.

FIG. 2 is a schematic plan view of the acoustic wave device according to the first preferred embodiment of the present invention.

FIG. 3 is a schematic elevational cross-sectional view of an acoustic wave device according to a first comparative example.

FIG. 4 is a schematic elevational cross-sectional view of an acoustic wave device according to a second comparative example.

FIGS. 5A to 5D are schematic elevational cross-sectional views for explaining a sacrificial layer forming process, a dielectric film forming process, and a support substrate bonding process in an example of a method for manufacturing an acoustic wave device according to the first preferred embodiment of the present invention.

FIGS. 6A to 6C are schematic elevational cross-sectional views for explaining a piezoelectric layer grinding process, a through hole forming process, an electrode forming process, and a sacrificial layer removing process in the example of the method for manufacturing an acoustic wave device according to the first preferred embodiment of the present invention.

FIG. 7 is a schematic elevational cross-sectional view of an acoustic wave device according to a second preferred embodiment of the present invention.

FIG. 8 is a schematic elevational cross-sectional view for explaining a sacrificial layer forming process in an example of a method for manufacturing an acoustic wave device according to the second preferred embodiment of the present invention.

FIGS. 9A to 9C are schematic elevational cross-sectional views for explaining a dielectric film forming process, a concave portion forming process, a piezoelectric substrate bonding process, and a piezoelectric layer grinding process in an example of a method for manufacturing an acoustic wave device according to the second preferred embodiment of the present invention.

FIG. 10 is a schematic elevational cross-sectional view of an acoustic wave device according to a first modification of the second preferred embodiment of the present invention.

FIG. 11 is a schematic plan view of a support member in the second preferred embodiment of the present invention.

FIG. 12A is a schematic cross-sectional view taken along an electrode finger opposing direction of an acoustic wave device according to a second modification of the second preferred embodiment of the present invention, and FIG. 12B is a schematic cross-sectional view taken along an electrode finger extending direction of the acoustic wave device according to the second modification of the second preferred embodiment of the present invention.

FIG. 13 is a schematic plan view of a laminated substrate including a support member and a piezoelectric layer in the second preferred embodiment of the present invention.

FIG. 14 is a schematic plan view of a support member in a third preferred embodiment of the present invention.

FIG. 15 is a schematic elevational cross-sectional view of an acoustic wave device according to a fourth preferred embodiment of the present invention.

FIG. 16 is a schematic elevational cross-sectional view of an acoustic wave device according to a modification of the fourth preferred embodiment of the present invention.

FIG. 17 is a schematic elevational cross-sectional view of an acoustic wave device according to a first reference example.

FIGS. 18A and 18B are schematic elevational cross-sectional views for explaining a concave portion forming process and a piezoelectric substrate bonding process in an example of a method for manufacturing an acoustic wave device according to the first reference example.

FIG. 19 is a schematic elevational cross-sectional view of an acoustic wave device according to a second reference example.

FIG. 20 is a schematic elevational cross-sectional view of an acoustic wave device according to a third reference example.

FIGS. 21A to 21C are schematic elevational cross-sectional views for explaining a lower electrode forming process, a piezoelectric substrate bonding process, and an upper electrode forming process in an example of a method for manufacturing an acoustic wave device according to the third reference example.

FIG. 22 is a schematic elevational cross-sectional view of an acoustic wave device according to a fourth reference example.

FIGS. 23A and 23B are schematic elevational cross-sectional views for explaining a lower electrode forming process, a dielectric film forming process, and a piezoelectric substrate bonding process in an example of a method for manufacturing an acoustic wave device according to the fourth reference example.

FIG. 24A is a simplified perspective view illustrating an outer appearance of an acoustic wave device using bulk waves in thickness sliding mode, and FIG. 24B is a plan view illustrating an electrode structure on a piezoelectric layer.

FIG. 25 is a sectional view of a portion taken along an A-A line of FIG. 24A.

FIG. 26A is a schematic elevational cross-sectional view for explaining Lamb waves that propagate through a piezoelectric film of an acoustic wave device, and FIG. 26B is a schematic elevational cross-sectional view for explaining bulk waves in a thickness sliding mode that propagate through a piezoelectric film in an acoustic wave device.

FIG. 27 is a diagram illustrating an amplitude direction of bulk waves in the thickness sliding mode.

FIG. 28 is a diagram illustrating resonance characteristics of an acoustic wave device using bulk waves in the thickness sliding mode.

FIG. 29 is a diagram illustrating a relationship between d/p and a fractional bandwidth as a resonator when a distance between centers of mutually-adjacent electrodes is p and a thickness of a piezoelectric layer is d.

FIG. 30 is a plan view of an acoustic wave device using bulk waves in the thickness sliding mode.

FIG. 31 is a diagram illustrating resonance characteristics of an acoustic wave device of a reference example with spurious responses.

FIG. 32 is a diagram illustrating a relationship between fractional bandwidths and phase rotation amounts of impedance of spurious responses which are standardized at about 180 degrees as magnitudes of spurious responses.

FIG. 33 is a diagram illustrating a relationship between d/2p and a metallization ratio MR.

FIG. 34 is a diagram showing a map of a fractional bandwidth with respect to Euler angles (0°, θ, ψ) of LiNbO₃, which is obtained by approximating d/p to 0 as much as possible.

FIG. 35 is a partial cutout perspective view for explaining an acoustic wave device using Lamb waves.

### DETAILED DESCRIPTION OF THE PREFERRED EMBODIMENTS

The present invention will be clarified below by describing preferred embodiments of the present invention with reference to the accompanying drawings.

Each of the preferred embodiments described in the present specification is exemplary and configurations can be partially exchanged or combined with each other between different preferred embodiments.

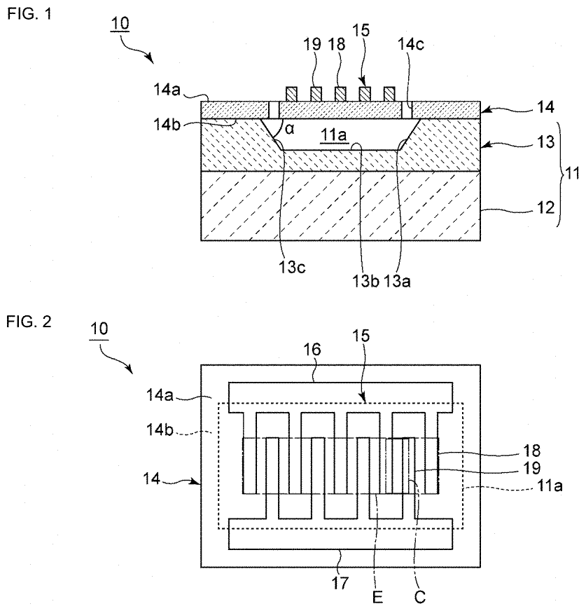

FIG. 1 is a schematic elevational cross-sectional view of an acoustic wave device according to a first preferred embodiment of the present invention. FIG. 2 is a schematic plan view of the acoustic wave device according to the first preferred embodiment.

An acoustic wave device 10 includes a support member 11 and a piezoelectric layer 14 as illustrated in FIG. 1. The support member 11 includes a support substrate 12 and a dielectric film 13. More specifically, the dielectric film 13 is provided on the support substrate 12. The piezoelectric layer 14 is provided on the dielectric film 13.

The piezoelectric layer 14 includes a first main surface 14a and a second main surface 14b. The first main surface 14a and the second main surface 14b are opposed to each other. The second main surface 14b is the main surface including the dielectric film 13 thereon.

On the first main surface 14a of the piezoelectric layer 14, an IDT electrode 15 as an excitation electrode is provided. Omitted in FIG. 1 and FIG. 2, a wiring electrode is provided on the first main surface 14a. The wiring electrode is electrically connected to the IDT electrode 15.

The IDT electrode 15 includes a first busbar 16, a second busbar 17, a plurality of first electrode fingers 18, and a plurality of second electrode fingers 19, as illustrated in FIG. 2. The first electrode finger 18 is a first electrode. The plurality of first electrode fingers 18 are periodically arranged. One end of each of the plurality of first electrode fingers 18 is connected to the first busbar 16. The second electrode finger 19 is a second electrode. The plurality of second electrode fingers 19 are periodically arranged. One end of each of the plurality of second electrode fingers 19 is connected to the second busbar 17. The plurality of first electrode fingers 18 and the plurality of second electrode fingers 19 are interdigitated with each other. The IDT electrode 15 may be a multilayer metal film or may be a single layer metal film. The first electrode finger 18 and the second electrode finger 19 will be sometimes referred to as merely the electrode finger below.

When a direction in which mutually-adjacent electrode fingers are opposed to each other is defined as an electrode finger opposing direction and a direction in which a plurality of electrode fingers extend is defined as an electrode finger extending direction, the electrode finger opposing direction is orthogonal or substantially orthogonal to the electrode finger extending direction in the present preferred embodiment. A region in which mutually-adjacent electrode fingers overlap with each other when viewed in the electrode finger opposing direction is an intersecting region E. The intersecting region E is a region, which includes from the electrode finger on one end to the electrode finger on the other end in the electrode finger opposing direction, in the IDT electrode 15. More specifically, the intersecting region E includes from an outer edge portion of the electrode finger on one end in the electrode finger opposing direction to an outer edge portion of the electrode finger on the other end in the electrode finger opposing direction.

The acoustic wave device 10 further includes a plurality of excitation regions C. When an AC voltage is applied to the IDT electrode 15, acoustic waves are excited in the plurality of excitation regions C. In the present preferred embodiment, the acoustic wave device 10 is configured to use bulk waves in a thickness sliding mode, such as a thickness sliding primary mode, for example. The excitation region C is a region in which mutually-adjacent electrode fingers overlap with each other when viewed in the electrode finger opposing direction, similarly to the intersecting region E. Each of the excitation regions C is a region between a pair of electrode fingers. More specifically, the excitation region C is a region from a center in the electrode finger opposing direction of one electrode finger to a center in the electrode finger opposing direction of the other electrode finger. Accordingly, the intersecting region E includes a plurality of excitation regions C. However, the acoustic wave device 10 may be configured to use, for example, plate waves. When the acoustic wave device 10 uses plate waves, the intersecting region E is an excitation region.

Referring back to FIG. 1, a cavity portion 11a is provided in the support member 11. The cavity portion 11a overlaps with at least a portion of the IDT electrode 15 in plan view. The plan view in the present specification indicates a direction viewed from the upper side in FIG. 1. The cavity portion 11a is a concave portion provided in the dielectric film 13 in the present preferred embodiment. More specifically, the dielectric film 13 includes a side wall surface 13a and a bottom surface 13b. The side wall surface 13a is connected with the bottom surface 13b. The side wall surface 13a and the bottom surface 13b face the cavity portion 11a. The cavity portion 11a is surrounded by the side wall surface 13a, the bottom surface 13b, and the second main surface 14b of the piezoelectric layer 14. The cavity portion 11a has a rectangular or substantially rectangular shape in plan view. The longitudinal direction of the cavity portion 11a in plan view is parallel or substantially parallel to the electrode finger opposing direction. The transverse direction of the cavity portion 11a in plan view is parallel or substantially parallel to the electrode finger extending direction. However, the shape of the cavity portion 11a in plan view is not limited to the above-described shape.

The side wall surface 13a in the dielectric film 13 includes an inclined portion 13c. More specifically, the inclined portion 13c is a portion that is inclined so that the width of the cavity portion 11a decreases with increasing distance away from the piezoelectric layer 14. The width of the cavity portion 11a is a dimension of the cavity portion 11a along the direction parallel or substantially parallel to the second main surface 14b of the piezoelectric layer 14. In a portion illustrated in FIG. 1, the dimension of the cavity portion 11a is a dimension along a direction that is parallel or substantially parallel to the electrode finger opposing direction and parallel or substantially parallel to the second main surface 14b. The entirety of the side wall surface 13a is the inclined portion 13c in the present preferred embodiment. However, the inclined portion 13c is only required to include at least an end portion, on the side including the piezoelectric layer 14, in the side wall surface 13a. The shape of a portion other than the inclined portion 13c in the side wall surface 13a is not particularly limited.

A through hole 14c is provided in the piezoelectric layer 14. The through hole 14c is used to define the cavity portion 11a when manufacturing the acoustic wave device 10. However, the piezoelectric layer 14 does not necessarily include the through hole 14c.

In the present preferred embodiment, an inclination angle α is, preferably from, for example, about 40° to about 80° inclusive when defining an angle between the inclined portion 13c of the side wall surface 13a in the dielectric film 13 and the second main surface 14b of the piezoelectric layer 14 as the inclination angle α. This configuration can reduce or prevent generation of cracks in the dielectric film 13 and sticking of the piezoelectric layer 14 to the dielectric film 13. This will be described below by comparing the present preferred embodiment with first and second comparative examples.

The first comparative example is different from the present preferred embodiment in that an inclination angle is smaller than about 40°. The second comparative example is different from the present preferred embodiment in that an inclination angle is larger than about 80°.

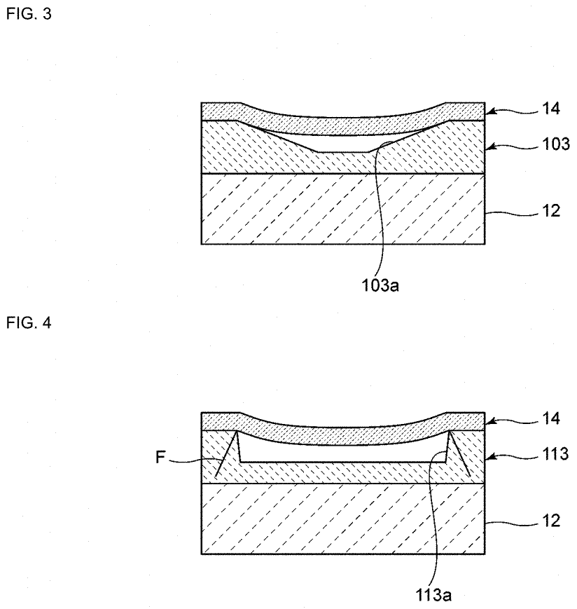

In the first comparative example illustrated in FIG. 3, the piezoelectric layer 14 sticks to a dielectric film 103. More specifically, the piezoelectric layer 14 sticks to a portion around an end portion, on the side including the piezoelectric layer 14, in a side wall surface 103a in the dielectric film 103. In the second comparative example illustrated in FIG. 4, a crack F is generated around an end portion, on the side including the piezoelectric layer 14, in a side wall surface 113a of a dielectric film 113.

The piezoelectric layer 14 may bend toward the support member 11 during, for example, manufacturing and use. On the other hand, the inclination angle α is about 40° or greater in the present preferred embodiment illustrated in FIG. 1. Thus, the inclination angle α is sufficiently large. This makes it difficult for the piezoelectric layer 14 to come into contact with the side wall surface 13a in the dielectric film 13. Sticking of the piezoelectric layer 14 to the dielectric film 13 can thus be reduced or prevented, being able to reduce or prevent deterioration of electrical characteristics of the acoustic wave device 10. Further, the inclination angle α of about 80° or smaller can reduce or prevent stress concentration at an interface between the support member 11 and the piezoelectric layer 14. This can reduce or prevent generation of cracks in the dielectric film 13 in the support member 11.

The following are examples of materials used for members in the acoustic wave device 10. The piezoelectric layer 14 of the present preferred embodiment is made of lithium niobate such as LiNbO₃, for example. In this specification, the statement that a certain member is made of a certain material includes the case where a minute amount of impurity is included such that the electrical characteristics of the acoustic wave device are not deteriorated. However, the material of the piezoelectric layer 14 is not limited to the above-described material but, for example, lithium tantalate such as LiTaO₃ may be used.

The dielectric film 13 is made of, for example, silicon oxide. However, the material of the dielectric film 13 is not limited to the above-described material. The dielectric film 13 preferably includes, for example, at least one of silicon oxide such as SiO₂, silicon nitride such as SiN, and aluminum oxide such as Al₂O₃.

The support substrate 12 is made of, for example, silicon. However, the material of the support substrate 12 is not limited to the above-described material, but, for example, piezoelectric materials such as aluminum oxide, lithium tantalate, lithium niobate, and crystal, various ceramics such as alumina, sapphire, magnesia, silicon nitride, aluminum nitride, silicon carbide, zirconia, cordierite, mullite, steatite, and forsterite, dielectrics such as diamond and glass, semiconductors such as gallium nitride; resin; or the like can also be used.

An example of a method for manufacturing the acoustic wave device 10 according to the present preferred embodiment will be described below.

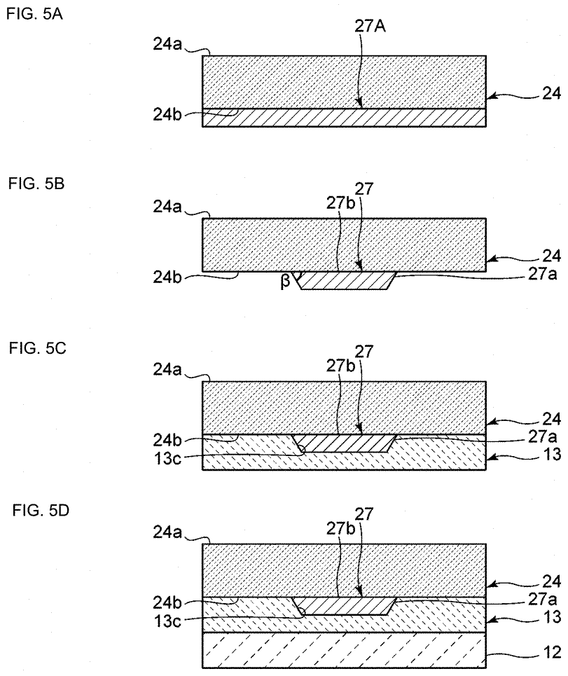

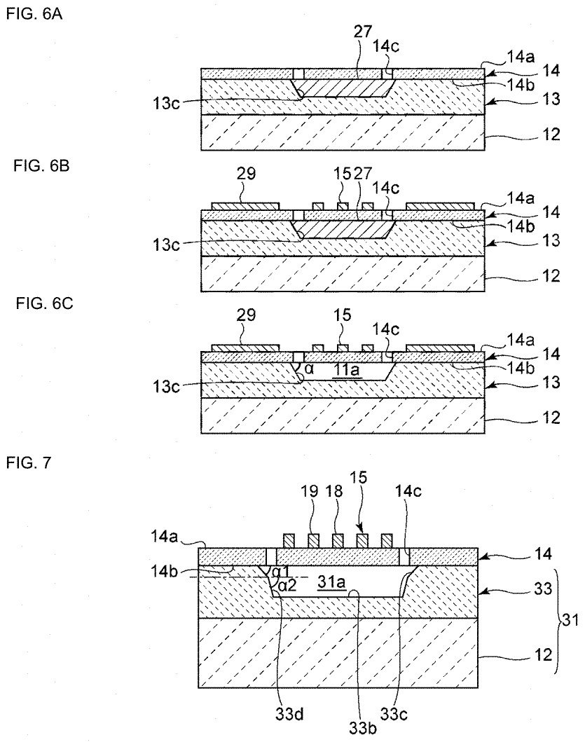

FIGS. 5A to 5D are schematic elevational cross-sectional views for explaining a sacrificial layer forming process, a dielectric film forming process, and a support substrate bonding process in an example of a method for manufacturing an acoustic wave device according to the first preferred embodiment. FIGS. 6A to 6C are schematic elevational cross-sectional views for explaining a piezoelectric layer grinding process, a through hole forming process, an electrode forming process, and a sacrificial layer removing process in the example of the method for manufacturing an acoustic wave device according to the first preferred embodiment.

A piezoelectric substrate 24 is prepared as illustrated in FIG. 5A. The piezoelectric substrate 24 is included in the piezoelectric layer. The piezoelectric substrate 24 includes a first main surface 24a and a second main surface 24b. The first main surface 24a and the second main surface 24b are opposed to each other. A sacrificial layer 27A is provided on the second main surface 24b. Then, the sacrificial layer 27A is patterned by performing etching, for example. The sacrificial layer 27 is subsequently planarized. Accordingly, the sacrificial layer 27 that is patterned and planarized obtains a bottom surface 27b and a side surface 27a as illustrated in FIG. 5B. The surface, on the side including the piezoelectric substrate 24, of the sacrificial layer 27 is the bottom surface 27b. The sacrificial layer 27A may be patterned so that an angle β is from, for example, about 40° to about 80° inclusive when an angle between the bottom surface 27b and the side surface 27a is defined as the angle β. For example, ZnO, SiO₂, Cu, or resin may be used as the material of the sacrificial layer 27.

Subsequently, the dielectric film 13 is formed on the second main surface 24b of the piezoelectric substrate 24 so as to cover at least the sacrificial layer 27, as illustrated in FIG. 5C. In the process illustrated in FIG. 5C, the dielectric film 13 also covers the second main surface 24b. The dielectric film 13 can be formed by, for example, sputtering or vacuum deposition. Then, the dielectric film 13 is planarized. For example, grinding or chemical mechanical polishing (CMP) may be used for the planarization of the dielectric film 13.

After that, the support substrate 12 is bonded to a main surface of the dielectric film 13, which is opposite to a main surface including the piezoelectric substrate 24 thereon, as illustrated in FIG. 5D. Then, the thickness of the piezoelectric substrate 24 is adjusted. More specifically, the thickness of the piezoelectric substrate 24 is reduced by, for example, grinding or polishing the main surface, which is not bonded to the support substrate 12, of the piezoelectric substrate 24. For example, grinding, CMP, ion slicing, or etching may be used to adjust the thickness of the piezoelectric substrate 24. The piezoelectric layer 14 is accordingly obtained as illustrated in FIG. 6A.

The through hole 14c is next formed in the piezoelectric layer 14 so that the through hole 14c extends to the sacrificial layer 27. The through hole 14c can be formed by reactive ion etching (RIE), for example. Then, the IDT electrode 15 and a wiring electrode 29 are provided on the first main surface 14a of the piezoelectric layer 14, as illustrated in FIG. 6B. At this time, the IDT electrode 15 is formed so that at least a portion of the IDT electrode 15 and the sacrificial layer 27 overlap with each other in plan view. Further at this time, the IDT electrode 15 is formed so that d/p is, for example, about 0.5 or lower when the thickness of the piezoelectric layer is d and a distance between centers of mutually-adjacent electrode fingers is p. The IDT electrode 15 and the wiring electrode 29 can be formed by, for example, sputtering or vacuum deposition.

Subsequently, the sacrificial layer 27 is removed through the through hole 14c. More specifically, the sacrificial layer 27 in the concave portion of the dielectric film 13 is removed by allowing etchant to flow in from the through hole 14c. The cavity portion 11a is thus formed. The acoustic wave device 10 is obtained as described thus far.

FIG. 7 is a schematic elevational cross-sectional view of an acoustic wave device according to a second preferred embodiment of the present invention.

The present preferred embodiment is different from the first preferred embodiment in that a side wall surface in a dielectric film 33 includes a first inclined portion 33c and a second inclined portion 33d. Other than the above-described point, the acoustic wave device of the present preferred embodiment has the same or substantially the same configuration as that of the acoustic wave device 10 of the first preferred embodiment.

The first inclined portion 33c is positioned closer to the piezoelectric layer 14 than the second inclined portion 33d. For example, when it is assumed that a first portion in a side wall surface is positioned closer to the piezoelectric layer 14 than a second portion, the first inclined portion 33c is the first portion and the second inclined portion 33d is the second portion.

Here, the first inclined portion 33c includes an end portion of the side wall surface on the side including the piezoelectric layer 14. That is, the first inclined portion 33c corresponds to an inclined portion. When an inclination angle of the first inclined portion 33c and an inclination angle of the second inclined portion 33d are defined as a first angle α1 and a second angle α2 respectively, α1<α2 is preferably satisfied. Thus, the inclination of the side wall surface becomes smaller toward the piezoelectric layer 14. More specifically, the inclination of the side wall surface changes in steps toward the piezoelectric layer 14. This configuration can effectively reduce or prevent stress applied to an interface between a support member 31 and the piezoelectric layer 14. Accordingly, generation of cracks in the dielectric film 33 of the support member 31 can be effectively reduced or prevented.

Further, the inclination angle of the first inclined portion 33c is also, for example, from about 40° to about 80° inclusive in the present preferred embodiment. Accordingly, it is possible to reduce or prevent sticking of the piezoelectric layer 14 to the dielectric film 33 and more reliably and effectively reduce or prevent generation of cracks in the dielectric film 33, similarly to the first preferred embodiment.

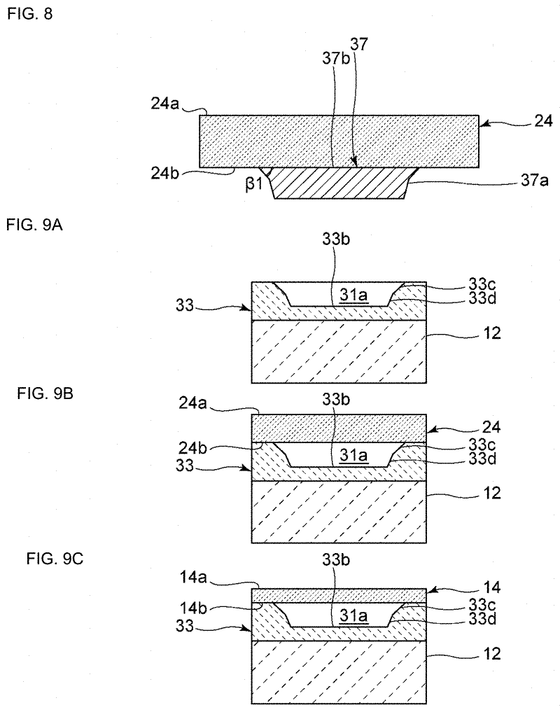

In forming the side wall surface of the dielectric film 33, a sacrificial layer 37 may be patterned so that the inclination angle of a side surface 37a of the sacrificial layer 37 changes in steps, as illustrated in FIG. 8. The sacrificial layer 37 may be patterned so that an angle β1 is, for example, from about 40° to about 80° inclusive when an angle between the vicinity of a portion, which is connected to a bottom surface 37b, in the side surface 37a and the bottom surface 37b is defined as the angle β1. Other processes can be performed in the same or substantially the same manner as in the example of the method for manufacturing the acoustic wave device 10 according to the first preferred embodiment described above.

Here, when forming a cavity portion 31a, the sacrificial layer 37 does not necessarily have to be used. Another example of a method for forming the cavity portion 31a will be described below.

FIGS. 9A to 9C are schematic elevational cross-sectional views for explaining a dielectric film forming process, a concave portion forming process, a piezoelectric substrate bonding process, and a piezoelectric layer grinding process in an example of a method for manufacturing an acoustic wave device according to the second preferred embodiment.

The dielectric film 33 is formed on the support substrate 12 as illustrated in FIG. 9A. Then, a concave portion is formed in the dielectric film 33. The concave portion can be formed by, for example, RIE. When using RIE, masking may be appropriately performed by, for example, lithography with respect to a portion other than a portion, on which the concave portion is to be formed, on the dielectric film 33. The first inclined portion 33c and the second inclined portion 33d of the dielectric film 33 may be formed by appropriately adjusting a selection ratio between a masking material and the dielectric film 33, which is a material to be etched. The cavity portion 31a according to the present preferred embodiment can be thus formed.

Then, the piezoelectric substrate 24 is bonded to a main surface of the dielectric film 33, which is opposite to the main surface having the support substrate 12 thereon, as illustrated in FIG. 9B. After that, the thickness of the piezoelectric substrate 24 is adjusted so as to obtain the piezoelectric layer 14, as illustrated in FIG. 9C. The piezoelectric layer grinding process for obtaining the piezoelectric layer 14 can be performed in the same or substantially the same manner as in the example of the method for manufacturing the acoustic wave device 10 according to the first preferred embodiment described above. The cavity portion 31a is surrounded by a bottom surface 33b and the side wall surface of the dielectric film 33 and the second main surface 14b of the piezoelectric layer 14, as illustrated in FIG. 9C.

The cavity portion 11a of the first preferred embodiment may be formed without using the sacrificial layer 27, in the same or substantially the same manner as the method described above.

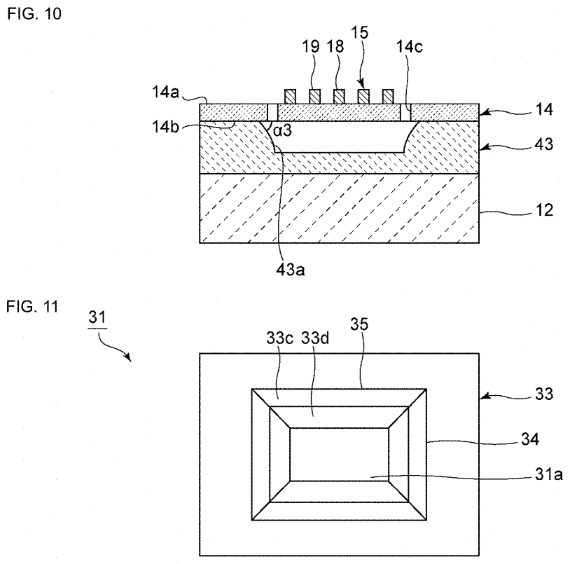

In the present preferred embodiment, the side wall surface in the dielectric film 33 includes the first inclined portion 33c and the second inclined portion 33d. The inclination of the inclined surface thus changes once. However, the number of times of inclination change of the side wall surface is not limited to once, and may be a plurality of times. Alternatively, the inclination on the side wall surface does not have to change in steps. For example, in a first modification of the second preferred embodiment illustrated in FIG. 10, a side wall surface 43a has a curved shape. The inclination of the side wall surface 43a continuously changes toward the piezoelectric layer 14. In the present modification, a portion including an end portion, on the side including the piezoelectric layer 14, in the side wall surface 43a is the inclined portion. An inclination angle α3 of the portion including the vicinity of the end portion, on the side including the piezoelectric layer 14, in the side wall surface 43a is, for example, from about 40° to about 80° inclusive. This configuration can also reduce or prevent generation of cracks in a dielectric film 43 and sticking of the piezoelectric layer 14 to the dielectric film 43 as is the case with the second preferred embodiment.

FIG. 11 is a schematic plan view of a support member in the second preferred embodiment.

The cavity portion 31a of the support member 31 has a rectangular or substantially rectangular shape in plan view as is the case with the first preferred embodiment. In this configuration, the side wall surface in the dielectric film 33 includes a plurality of side wall portions. More specifically, the side wall surface includes a pair of first side wall portions 34 and a pair of second side wall portions 35. The pair of first side wall portions 34 are opposed to each other in a longitudinal direction of the cavity portion 31a, in the present preferred embodiment. The pair of second side wall portions 35 are opposed to each other in a transverse direction. However, the shape of the cavity portion 31a in plan view is not limited to the rectangular or substantially rectangular shape. When the side wall surface includes a plurality of side wall portions, the shape of the cavity portion 31a in plan view may be, for example, a square or substantially square shape or a polygonal of substantially polygonal shape other than a quadrangular shape.

On the first side wall portions 34 and the second side wall portions 35, respective first inclined portions 33c and respective second inclined portions 33d are configured in the same or substantially the same manner. Accordingly, the inclination angles of the first inclined portions 33c are the same or substantially the same as each other in the first side wall portion 34 and the second side wall portion 35.

Here, inclination modes may differ from each other between the first side wall portion 34 and the second side wall portion 35. For example, in a second modification of the second preferred embodiment, an inclination angle of a first inclined portion 54c in a first side wall portion 54 illustrated in FIG. 12A is larger than an inclination angle of a first inclined portion 55c in a second side wall portion 55 illustrated in FIG. 12B. Thus, inclination angles may differ between at least two first inclined portions among a plurality of side wall portions. The inclination angle of the first inclined portion 54c in the first side wall portion 54 and the inclination angle of the first inclined portion 55c in the second side wall portion 55 are, for example, from about 40° to about 80° inclusive. This configuration can also reduce or prevent generation of cracks in a dielectric film 53 and sticking of the piezoelectric layer 14 to the dielectric film 53 as is the case with the second preferred embodiment. A dashed line in FIG. 12B indicates an interface between the first busbar 16 and the first electrode fingers 18.

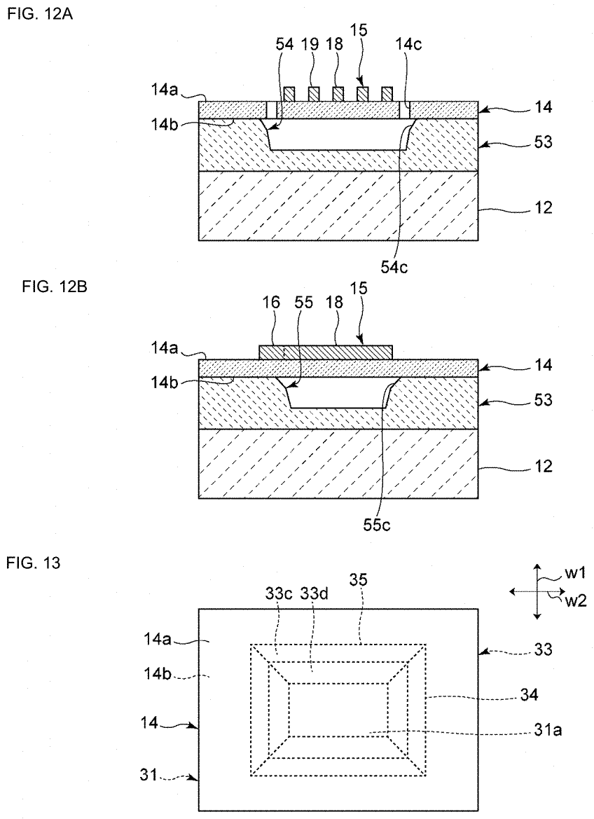

FIG. 13 is a schematic plan view of a laminated substrate including a support member and a piezoelectric layer in the second preferred embodiment.

In the second preferred embodiment, the piezoelectric layer 14 is made of, for example, lithium niobate. The piezoelectric layer 14 accordingly has anisotropy in a linear expansion coefficient thereof. More specifically, the piezoelectric layer 14 includes a first direction w1 and a second direction w2 that are orthogonal or substantially orthogonal to each other, as illustrated in FIG. 13. The linear expansion coefficient in the first direction w1 and the linear expansion coefficient in the second direction w2 are different from each other. For example, the linear expansion coefficient in the first direction w1 may be a maximum in the piezoelectric layer 14. The linear expansion coefficient in the second direction w2 may be a minimum in the piezoelectric layer 14. However, the relationship between the linear expansion coefficients and the first and second directions w1 and w2 is not limited to this. Further, the direction in which the linear expansion coefficient is a maximum does not have to be parallel or substantially parallel to the first main surface 14a or the second main surface 14b of the piezoelectric layer 14. The same can be applied to the direction in which the linear expansion coefficient is a minimum. Here, the first direction w1 and the second direction w2 do not necessarily have to be orthogonal or substantially orthogonal to each other but may intersect with each other.

In the dielectric film 33, the first side wall portion 34 extends along the first direction w1. The second side wall portion 35 extends along the second direction w2. Accordingly, the inclination angles in the first side wall portion 34 and the second side wall portion 35 can be adjusted to be suitable for the linear expansion coefficient of the piezoelectric layer 14. This configuration can more reliably relieve stress applied to the interface between the support member 31 and the piezoelectric layer 14. Accordingly, generation of cracks in the dielectric film 33 can be more reliably reduced or prevented. The first side wall portion and the second side wall portion may also similarly extend in accordance with anisotropy of the linear expansion coefficient of the piezoelectric layer 14, in other preferred embodiments and modifications. For example, in the second modification of the second preferred embodiment, the inclination angle of the first inclined portion 54c in the first side wall portion 54 and the inclination angle of the first inclined portion 55c in the second side wall portion 55 are different from each other. Thus, each inclination angle can be favorably adjusted in accordance with a corresponding linear expansion coefficient.

The support substrate 12 may have anisotropy in its linear expansion coefficient. For example, when the support substrate 12 is made of silicon and the main surface, on the side including the piezoelectric layer 14, of the support substrate 12 is a (111) surface or a (110) surface, the support substrate 12 has anisotropy in its linear expansion coefficients. The support substrate 12 may have a third direction and a fourth direction that are orthogonal or substantially orthogonal to each other, in this configuration. The linear expansion coefficient in the third direction and the linear expansion coefficient in the fourth direction are different from each other. Further, the first side wall portion 34 may extend along, for example, the third direction, in the dielectric film 33. The second side wall portion 35 may extend along the fourth direction. In this configuration, the inclination angles in the first side wall portion 34 and the second side wall portion 35 can be adjusted to be suitable for the linear expansion coefficient of the support substrate 12. Accordingly, stress applied to the interface between the support member 31 and the piezoelectric layer 14 can be more reliably relieved. The first side wall portion and the second side wall portion may also similarly extend in accordance with anisotropy of the linear expansion coefficient of the support substrate 12, in other preferred embodiments and modifications. Here, the third direction and the fourth direction do not necessarily have to be orthogonal or substantially orthogonal to each other but may intersect with each other.

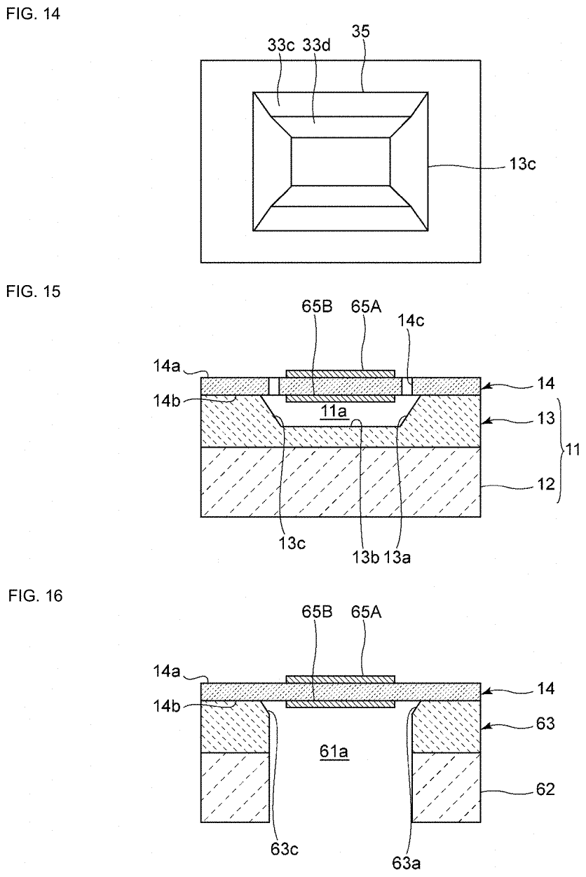

FIG. 14 is a schematic plan view of a support member in a third preferred embodiment of the present invention.

The present preferred embodiment is different from the second preferred embodiment in that inclination of a portion of a side wall surface in a dielectric film does not change in the same manner as the first preferred embodiment. More specifically, inclination of the inclined portion 13c in the first side wall portion does not change, as is the case with the first preferred embodiment. On the other hand, inclination in the second side wall portion 35 changes once as is the case with the second preferred embodiment. Other than the above-described point, the acoustic wave device of the present preferred embodiment has the same or substantially the same configuration as that of the acoustic wave device of the second preferred embodiment.

Inclination of at least one of a plurality of side wall portions may change once or more in the present preferred embodiment. The inclination angle of the inclined portion 13c in the first side wall portion and the inclination angle of the first inclined portion 33c in the second side wall portion 35 are, for example, from about 40° to about 80° inclusive. This configuration can reduce or prevent generation of cracks in the dielectric film and sticking of the piezoelectric layer 14 to the dielectric film.

For example, one of the first side wall portion and the second side wall portion may have a curved shape. Alternatively, for example, inclination may change once or more and the number of times of inclination change may be different between the first side wall portion and the second side wall portion. In these configurations as well, the inclination angle of the vicinity of the end portion, on the side having the piezoelectric layer 14, in the inclined portion may be, for example, from about 40° to about 80° inclusive. Accordingly, generation of cracks in the dielectric film and sticking of the piezoelectric layer 14 to the dielectric film can be reduced or prevented.

FIG. 15 is a schematic elevational cross-sectional view of an acoustic wave device according to a fourth preferred embodiment of the present invention.

The present preferred embodiment is different from the first preferred embodiment in that an excitation electrode includes an upper electrode 65A and a lower electrode 65B. The upper electrode 65A is provided on the first main surface 14a of the piezoelectric layer 14. The lower electrode 65B is provided on the second main surface 14b. Other than the above-described point, the acoustic wave device of the present preferred embodiment has the same or substantially the same configuration as that of the acoustic wave device 10 of the first preferred embodiment.

The upper electrode 65A and the lower electrode 65B are opposed to each other with the piezoelectric layer 14 interposed therebetween. A portion where the upper and lower electrodes 65A and 65B and the piezoelectric layer 14 overlap with each other in plan view is an excitation portion. A bulk wave is excited in the excitation portion. Here, the cavity portion 11a overlaps with at least a portion of the upper and lower electrodes 65A and 65B in plan view. More specifically, the cavity portion 11a overlaps with the excitation portion in plan view.

The inclination angle of the inclined portion 13c in the dielectric film 13 is also, for example, from about 40° to about 80° inclusive in the present preferred embodiment. Accordingly, generation of cracks in the dielectric film 13 and sticking of the piezoelectric layer 14 to the dielectric film 13 can be reduced or prevented as is the case with the first preferred embodiment.

The cavity portion 11a is a hollow portion surrounded by the bottom surface 13b and the side wall surface 13a in the dielectric film 13 and the second main surface 14b of the piezoelectric layer 14, in the present preferred embodiment. Here, the cavity portion 11a may be a through hole provided in the support member 11. For example, in a modification of the fourth preferred embodiment illustrated in FIG. 16, a cavity portion 61a is a through hole penetrating through a support substrate 62 and a dielectric film 63. A side wall surface 63a in the dielectric film 63 includes an inclined portion 63c. The inclined portion 63c includes an end portion of the side wall surface 63a on the side having the piezoelectric layer 14, as is the case with the fourth preferred embodiment. Further, the inclination angle of the inclined portion 63c is, for example, from about 40° to about 80° inclusive. This configuration can reduce or prevent generation of cracks in the dielectric film 63 and sticking of the piezoelectric layer 14 to the dielectric film 63.

In each preferred embodiment and modification described above, the cavity portion is provided in the dielectric film in the support member and the inclination angle of the inclined portion is set to be, for example, from about 40° to about 80° inclusive. In the following, first to third reference examples will be described in which a support member does not include a dielectric film. In this configuration, a cavity portion may be provided in a support substrate and a side wall surface facing the cavity portion may include an inclined surface which is the same as or similar to that of each preferred embodiment and the like described above. Specifically, the inclined surface may include at least an end portion, on the side including a piezoelectric layer, in a side wall surface and an angle of an inclined portion may be, for example, from about 40° to about 80° inclusive. The inclination on the side wall surface may change similarly to the second preferred embodiment and the like. In this configuration, it is only required that the inclination angle of the vicinity of the end portion, on the side including the piezoelectric layer, in the inclined portion is from about 40° to about 80° inclusive. Accordingly, generation of cracks in the support substrate as a support member and sticking of the piezoelectric layer to the support member can be reduced or prevented.

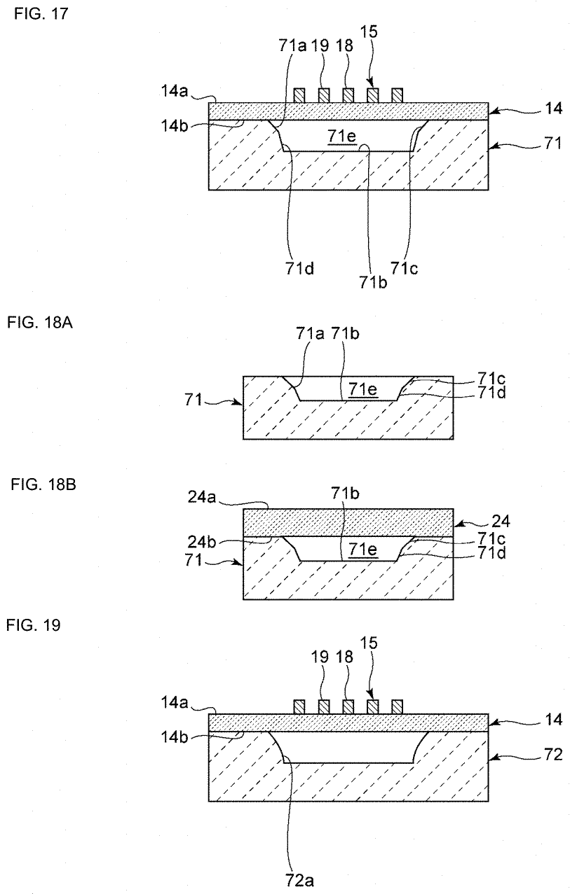

In the first reference example illustrated in FIG. 17, a concave portion 71e is provided in a support substrate 71. This concave portion 71e is a cavity portion of the support substrate 71 defining and functioning as a support member. The support substrate 71 includes a side wall surface 71a and a bottom surface 71b. The side wall surface 71a is connected with the bottom surface 71b. The side wall surface 71a and the bottom surface 71b face the cavity portion. The cavity portion is surrounded by the side wall surface 71a, the bottom surface 71b, and the second main surface 14b of the piezoelectric layer 14. The side wall surface 71a includes a first inclined portion 71c and a second inclined portion 71d. The first inclined portion 71c is positioned closer to the piezoelectric layer 14 than the second inclined portion 71d. The first inclined portion 71c includes an end portion, on the side including the piezoelectric layer 14, in the side wall surface 71a. An inclination angle of the first inclined portion 71c is smaller than an inclination angle of the second inclined portion 71d. Thus, the inclination of the side wall surface 71a changes in steps toward the piezoelectric layer 14. The inclination angle of the first inclined portion 71c is, for example, from about 40° to about 80° inclusive. Here, an excitation electrode in the present reference example is the IDT electrode 15 which is the same or substantially the same as that of the first preferred embodiment.

In manufacturing the acoustic wave device of the present reference example, the concave portion 71e is provided in the support substrate 71, for example, as illustrated in FIG. 18A. The concave portion 71e can be made of, for example, RIE. When using RIE, masking may be appropriately performed by, for example, lithography with respect to a portion other than a portion, on which the concave portion is to be provided, on the support substrate 71. The first inclined portion 71c and the second inclined portion 71d of the support substrate 71 may be formed by appropriately adjusting a selection ratio between a masking material and the support substrate 71, which is a material to be etched. The cavity portion of the present reference example can thus be formed.

After that, the piezoelectric substrate 24 is bonded to the support substrate 71 to close the concave portion 71e, as illustrated in FIG. 18B. For example, direct bonding, plasma-activated bonding, or atomic diffusion bonding can be used for bonding between the support substrate 71 and the piezoelectric substrate 24. Subsequent processes can be performed in the same or substantially the same manner as in the example of the method for manufacturing the acoustic wave device 10 according to the first preferred embodiment described above.

In the second reference example illustrated in FIG. 19, a side wall surface 72a in a support substrate 72 has a curved shape. The inclination of the side wall surface 72a continuously changes toward the piezoelectric layer 14. In the present reference example, a portion including an end portion, on the side including the piezoelectric layer 14, in the side wall surface 72a is an inclined portion which is the same or substantially the same as that of a preferred embodiment of the present invention. An inclination angle of the vicinity of the end portion, on the side including the piezoelectric layer 14, in the side wall surface 72a is, for example, from about 40° to about 80° inclusive.

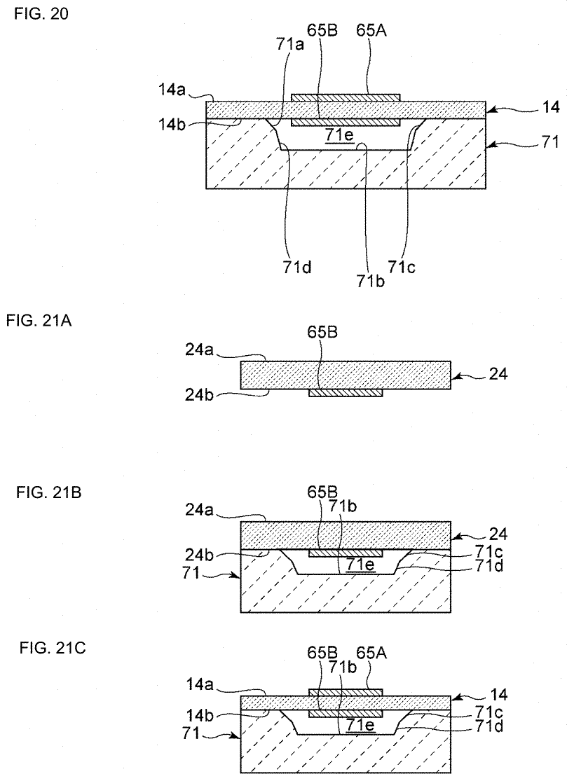

In the third reference example illustrated in FIG. 20, the support substrate 71 which is the same or substantially the same as that in the first reference example illustrated in FIG. 17 is provided. On the other hand, an excitation electrode is the upper electrode 65A and the lower electrode 65B which are the same or substantially the same as those of the fourth preferred embodiment. In manufacturing the acoustic wave device of the present reference example, the concave portion 71e may be formed in the support substrate 71 in the same or substantially the same manner as in the example of the method for manufacturing the acoustic wave device according to the first reference example, for example. Then, the lower electrode 65B is formed on the second main surface 24b of the piezoelectric substrate 24, as illustrated in FIG. 21A. The lower electrode 65B can be formed by, for example, sputtering or vacuum deposition. After that, the piezoelectric substrate 24 is bonded to the support substrate 71 to close the concave portion 71e, as illustrated in FIG. 21B. At this time, the piezoelectric substrate 24 is bonded to the support substrate 71 so that the lower electrode 65B is positioned in the concave portion 71e. For example, direct bonding, plasma-activated bonding, or atomic diffusion bonding can be used for bonding between the support substrate 71 and the piezoelectric substrate 24. Subsequently, the thickness of the piezoelectric substrate 24 is adjusted so as to obtain the piezoelectric layer 14, as illustrated in FIG. 21C. The piezoelectric layer grinding process for obtaining the piezoelectric layer 14 can be performed in the same or substantially the same manner as in the example of the method for manufacturing the acoustic wave device 10 according to the first preferred embodiment described above. Then, the upper electrode 65A is formed on the first main surface 14a of the piezoelectric layer 14. At this time, the upper electrode 65A is formed so that the upper electrode 65A overlaps with the lower electrode 65B in plan view. The upper electrode 65A can be formed by, for example, sputtering or vacuum deposition.

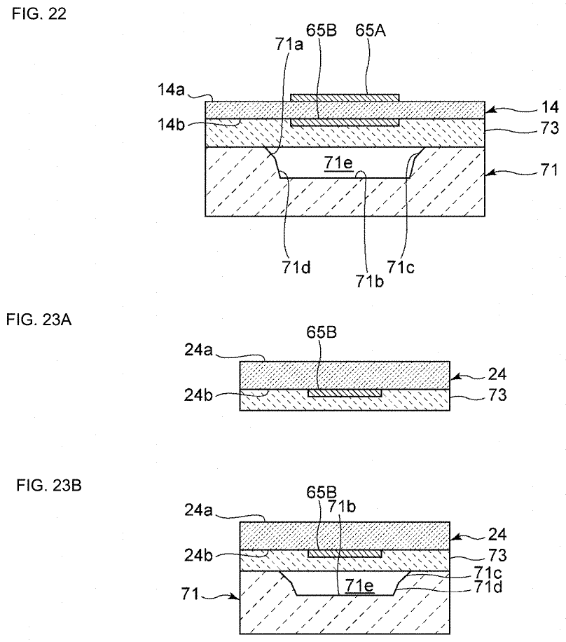

FIG. 22 is a schematic elevational cross-sectional view of an acoustic wave device according to a fourth reference example.

The present reference example is different from the third reference example in that a dielectric film 73 is provided between the support substrate 71 and the piezoelectric layer 14. In the present reference example, a cavity portion is not provided in the dielectric film 73 but a cavity portion is provided only in the support substrate 71. Cracks are less likely generated in the support substrate 71 also in the present reference example, as is the case with the third reference example.

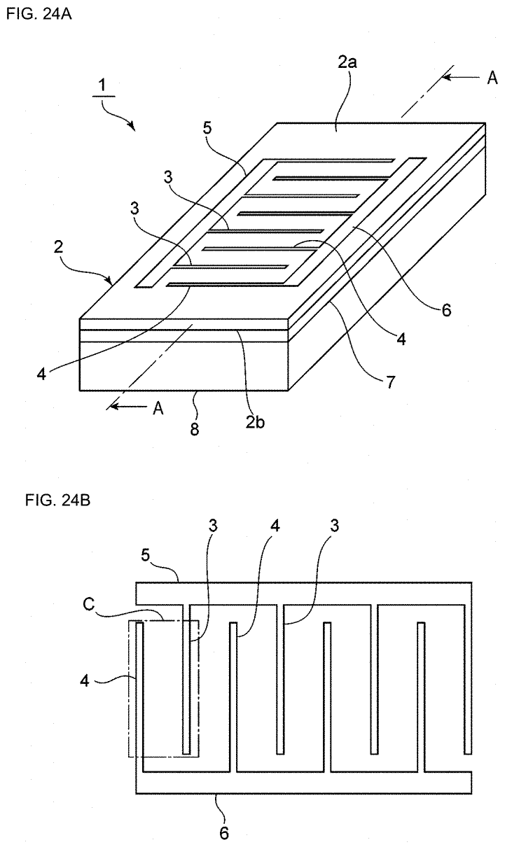

In manufacturing the acoustic wave device of the present reference example, the concave portion 71e may be formed in the support substrate 71 in the same or substantially the same manner as in the example of the method for manufacturing the acoustic wave device according to the first reference example, for example. Then, the lower electrode 65B is formed on the second main surface 24b of the piezoelectric substrate 24, as illustrated in FIG. 23A. The lower electrode 65B can be formed by, for example, sputtering or vacuum deposition. Subsequently, the dielectric film 73 is formed on the second main surface 24b to cover at least a portion of the lower electrode 65B. The dielectric film 73 can be formed by, for example, sputtering or vacuum deposition. After that, the support substrate 71 is bonded to a main surface of the dielectric film 73, which is opposite to the main surface having the piezoelectric substrate 24 thereon, as illustrated in FIG. 23B. Subsequent processes can be performed in the same or substantially the same manner as in the example of the method for manufacturing the acoustic wave device according to the third reference example described above.

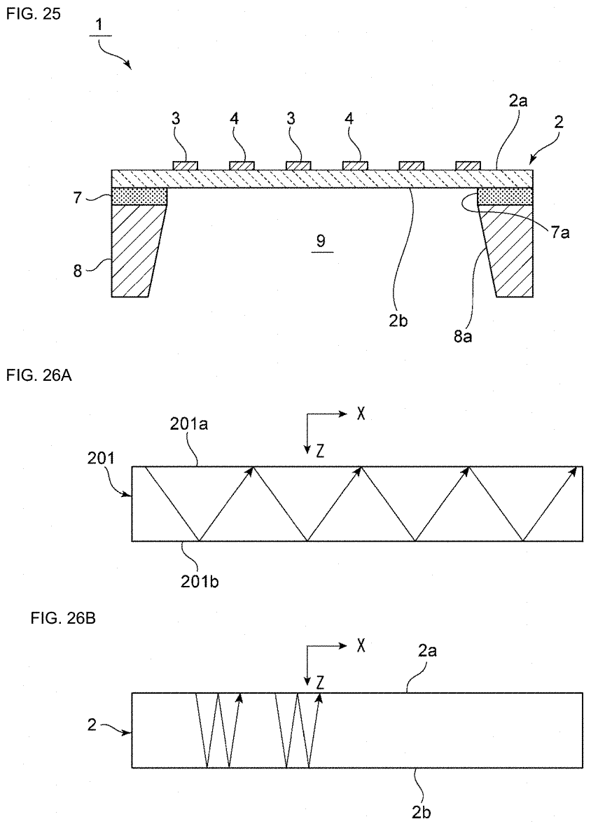

FIG. 24A is a simplified perspective view illustrating an outer appearance of an acoustic wave device using bulk waves in thickness sliding mode, and FIG. 24B is a plan view illustrating an electrode structure on a piezoelectric layer. FIG. 25 is a sectional view of a portion taken along an A-A line of FIG. 24A.

An acoustic wave device 1 includes a piezoelectric layer 2 made of, for example, LiNbO₃. The piezoelectric layer 2 may be made of, for example, LiTaO₃ instead. A cut-angle of LiNbO₃ and LiTaO₃ is Z-cut, but the cut-angle may be rotated Y-cut or X-cut. Not especially limited, the thickness of the piezoelectric layer 2 is preferably, for example, from about 40 nm to about 1000 nm inclusive, and more preferably, for example, from about 50 nm to about 1000 nm inclusive, so as to obtain effective excitation in the thickness sliding mode. The piezoelectric layer 2 includes a first main surface 2a and a second main surface 2b that are opposed to each other. An electrode 3 and an electrode 4 are provided on the first main surface 2a. Here, the electrode 3 is an example of the “first electrode” and the electrode 4 is an example of the “second electrode”. In FIGS. 24A and 24B, a plurality of electrodes 3 are connected to a first busbar 5. A plurality of electrodes 4 are connected to a second busbar 6. The plurality of electrodes 3 and the plurality of electrodes 4 are interdigitated with each other. The electrode 3 and the electrode 4 have a rectangular or substantially rectangular shape and have a longitudinal direction. In a direction orthogonal or substantially orthogonal to the longitudinal direction, the electrode 3 and adjacent electrode 4 are opposed to each other. Both of the longitudinal direction of the electrodes 3 and 4 and the direction orthogonal or substantially orthogonal to the longitudinal direction of the electrodes 3 and 4 are directions intersecting with the thickness direction of the piezoelectric layer 2. Therefore, it can be said that the electrode 3 and the adjacent electrode 4 are opposed to each other in the direction intersecting with the thickness direction of the piezoelectric layer 2. Here, the longitudinal direction of the electrodes 3 and 4 may be exchanged with the direction orthogonal or substantially orthogonal to the longitudinal direction of the electrodes 3 and 4 illustrated in FIGS. 24A and 24B. Namely, the electrodes 3 and 4 may extend in a direction in which the first busbar 5 and the second busbar 6 extend in FIGS. 24A and 24B. In this configuration, the first busbar 5 and the second busbar 6 extend in the direction in which the electrodes 3 and 4 extend in FIGS. 24A and 24B. A plurality of structures, each of which include a pair of mutually-adjacent electrodes 3 and 4, are provided in the direction orthogonal or substantially orthogonal to the longitudinal direction of the electrodes 3 and 4. In the structure, the electrode 3 is connected to one potential and the electrode 4 is connected to the other potential. Here, the state in which the electrode 3 and the electrode 4 are mutually adjacent is not the state in which the electrode 3 and the electrode 4 are arranged to be in direct contact with each other, but the state in which the electrode 3 and the electrode 4 are arranged with an interval therebetween. Further, when the electrode 3 and the electrode 4 are mutually adjacent, no other electrodes, as well as other electrodes 3 and 4, connected to a hot electrode or a ground electrode are arranged between these mutually-adjacent electrodes 3 and 4. The number of pairs does not have to be an integer, but the pairs may be 1.5 pairs or 2.5 pairs, for example. The distance between the centers of the electrodes 3 and 4, that is, the pitch is preferably, for example, in a range from about 1 μm to about 10 μm inclusive. The width of the electrodes 3 and 4, namely, the dimension in the opposing direction of the electrodes 3 and 4 is preferably, for example, in a range from about 50 nm to about 1000 nm inclusive, and more preferably, for example, in a range from about 150 nm to about 1000 nm inclusive. The distance between the centers of the electrodes 3 and 4 is the distance obtained by connecting the center of the electrode 3 in the dimension (width dimension) in the direction orthogonal or substantially orthogonal to the longitudinal direction of the electrode 3 and the center of the electrode 4 in the dimension (width dimension) in the direction orthogonal or substantially orthogonal to the longitudinal direction of the electrode 4 with each other.

The acoustic wave device 1 includes the Z-cut piezoelectric layer and therefore, the direction orthogonal or substantially orthogonal to the longitudinal direction of the electrodes 3 and 4 is a direction orthogonal or substantially orthogonal to a polarization direction of the piezoelectric layer 2. This does not apply when piezoelectric materials of other cut-angles are used as the piezoelectric layer 2. Here, “orthogonal” is not limitedly used for the exactly orthogonal configuration but may be used for the substantially orthogonal configuration (within the range about 90°±10°, for example, of an angle between the direction orthogonal to the longitudinal direction of the electrodes 3 and 4 and a polarization direction).

A support member 8 is laminated on the second main surface 2b side of the piezoelectric layer 2 with an insulation layer 7 interposed therebetween. The insulation layer 7 and the support member 8 have a frame shape and include through holes 7a and 8a respectively as illustrated in FIG. 25. A cavity portion 9 is thus provided. The cavity portion 9 is structured so as not to disturb vibration in the excitation region C of the piezoelectric layer 2. Therefore, the support member 8 is laminated on the second main surface 2b with the insulation layer 7 interposed therebetween, on a position which does not overlap with a portion including at least a pair of electrodes 3 and 4. Here, the insulation layer 7 does not necessarily have to be provided. Thus, the support member 8 can be directly or indirectly laminated on the second main surface 2b of the piezoelectric layer 2.

The insulation layer 7 is made of, for example, silicon oxide. An appropriate insulating material such as, for example, silicon oxynitride and alumina can be used as well as silicon oxide. The support member 8 is made of, for example, Si. A plane orientation of Si on a surface on the piezoelectric layer 2 side may be (100), (110), and (111). Si of the support member 8 preferably has a high resistivity of, for example, about 4 kΩ or higher. The support member 8 can also be made of an appropriate insulating material or semiconductor material.

Examples used as the material of the support member 8 include piezoelectric materials such as aluminum oxide, lithium tantalate, lithium niobate, and crystal, various ceramics such as alumina, magnesia, sapphire, silicon nitride, aluminum nitride, silicon carbide, zirconia, cordierite, mullite, steatite, and forsterite, dielectrics such as diamond and glass, and semiconductors such as gallium nitride.

The plurality of electrodes 3 and 4 and the first and second busbars 5 and 6 are made of appropriate metal or alloy such as, for example, Al and AlCu alloy. In the present preferred embodiment, the electrodes 3 and 4 and the first and second busbars 5 and 6 have a structure in which, for example, an Al film is laminated on a Ti film. However, an adhesion layer other than the Ti film may be used.

An AC voltage is applied between the plurality of electrodes 3 and the plurality of electrodes 4 for driving. More specifically, an AC voltage is applied between the first busbar 5 and the second busbar 6. This can provide resonance characteristics using bulk waves in the thickness sliding mode that are excited in the piezoelectric layer 2. When the thickness of the piezoelectric layer 2 is d and the distance between centers of any mutually-adjacent electrodes 3 and 4 among the plurality of pairs of electrodes 3 and 4 is p, d/p is, for example, about 0.5 or lower in the acoustic wave device 1. Therefore, bulk waves in the thickness sliding mode are effectively excited and favorable resonance characteristics can be obtained. d/p is more preferably, for example, about 0.24 or lower, which can provide more favorable resonance characteristics.

Since the acoustic wave device 1 has the above-described configuration, a Q value is not easily lowered even when the number of pairs of electrodes 3 and 4 is reduced to promote downsizing. This is because propagation loss is small even when reducing the number of electrode fingers in reflectors on both sides. Further, the number of electrode fingers can be reduced because of the use of bulk waves in the thickness sliding mode. The difference between Lamb waves used in an acoustic wave device and bulk waves in the thickness sliding mode described above will be described with reference to FIGS. 26A and 26B.

FIG. 26A is a schematic elevational cross-sectional view for explaining Lamb waves propagating through a piezoelectric film of an acoustic wave device as the one described in Japanese Unexamined Patent Application Publication No. 2012-257019. Here, waves propagate in a piezoelectric film 201 as illustrated with arrows. A first main surface 201a and a second main surface 201b are opposed to each other in the piezoelectric film 201, and a thickness direction connecting the first main surface 201a and the second main surface 201b is the Z direction. The X direction is a direction in which electrode fingers of an IDT electrode are aligned. As illustrated in FIG. 26A, in Lamb waves, the waves propagate in the X direction as illustrated in the drawing. Even though the entire piezoelectric film 201 vibrates, the waves propagate in the X direction because the waves are plate waves. Therefore, reflectors are arranged on both sides so as to obtain resonance characteristics. Consequently, wave propagation loss is generated, and when downsizing is promoted, namely, when the number of pairs of electrode fingers is reduced, a Q value is lowered.

On the other hand, vibration displacement is in a thickness sliding direction in the acoustic wave device 1. Therefore, waves mostly propagate and resonate in the direction connecting the first main surface 2a and the second main surface 2b of the piezoelectric layer 2, namely, in the Z direction as illustrated in FIG. 26B. That is, X-direction components of the waves are remarkably smaller than Z-direction components. Resonance characteristics can be obtained by this wave propagation in the Z direction and therefore, propagation loss is not likely to be generated even when the number of electrode fingers of reflectors is reduced. Further, even when the number of pairs of electrodes including the electrodes 3 and 4 is reduced to promote downsizing, a Q value is not easily lowered.

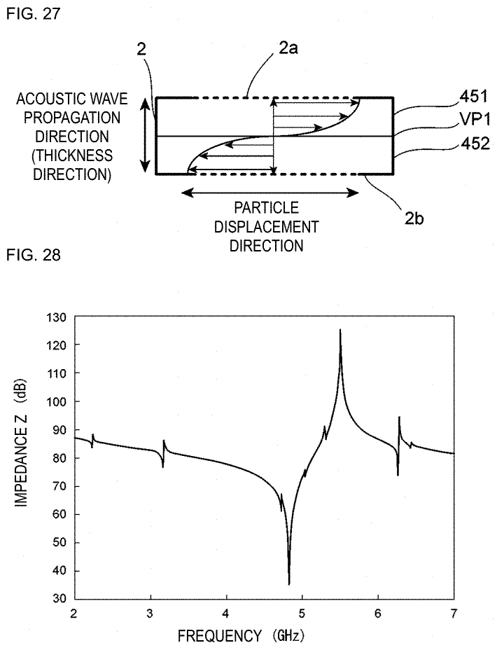

An amplitude direction of a bulk wave in the thickness sliding mode is reversed between a first region 451 included in the excitation region C of the piezoelectric layer 2 and a second region 452 included in the excitation region C, as illustrated in FIG. 27. FIG. 27 schematically illustrates a bulk wave obtained when applying a voltage, by which the electrode 4 has a higher potential than the electrode 3, between the electrode 3 and the electrode 4. The first region 451 is a region between a virtual plane VP1, which is orthogonal or substantially orthogonal to the thickness direction of the piezoelectric layer 2 and divides the piezoelectric layer 2 into two, and the first main surface 2a, in the excitation region C. The second region 452 is a region between the virtual plane VP1 and the second main surface 2b, in the excitation region C.

In the acoustic wave device 1, at least one pair of electrodes including the electrode 3 and the electrode 4 is arranged, as described above. However, waves do not propagate in the X direction in the acoustic wave device 1 and therefore, the number of pairs of electrodes including the electrodes 3 and 4 does not have to be plural. That is, it is sufficient if at least one pair of electrodes is provided.

For example, the electrode 3 is an electrode connected to a hot potential and the electrode 4 is an electrode connected to a ground potential. However, the electrode 3 may be connected to a ground potential and the electrode 4 may be connected to a hot potential. In the present preferred embodiment, at least one pair of electrodes is an electrode connected to a hot potential or an electrode connected to a ground potential as described above, and no floating electrodes are provided.

FIG. 28 is a diagram illustrating resonance characteristics of the acoustic wave device illustrated in FIG. 25. The followings are the design parameters of the acoustic wave device 1 having the resonance characteristics.

Piezoelectric layer 2: LiNbO₃ of Euler angles (0°, 0°, 90°), thickness=about 400 nm.

A region in which the electrode 3 and the electrode 4 overlap with each other when viewed in the direction orthogonal or substantially orthogonal to the longitudinal direction of the electrode 3 and the electrode 4, namely, the length of the excitation region C=about 40 μm, the number of pairs of electrodes composed of the electrodes 3 and 4=21 pairs, the distance between centers of electrodes=about 3 μm, the width of the electrodes 3 and 4=about 500 nm, d/p=about 0.133.

Insulation layer 7: a silicon oxide film having the thickness of about 1 μm.

Support member 8: Si.

The length of the excitation region C is a dimension of the excitation region C along the longitudinal direction of the electrodes 3 and 4.

The present preferred embodiment uses the configuration in which the inter-electrode distances among a plurality of pairs of electrodes including the electrodes 3 and 4 are all equal or substantially equal to each other. That is, the electrodes 3 and the electrodes 4 are arranged at equal or substantially equal pitches.

As is apparent from FIG. 28, favorable resonance characteristics in which a fractional bandwidth is about 12.5% can be obtained even without providing reflectors.

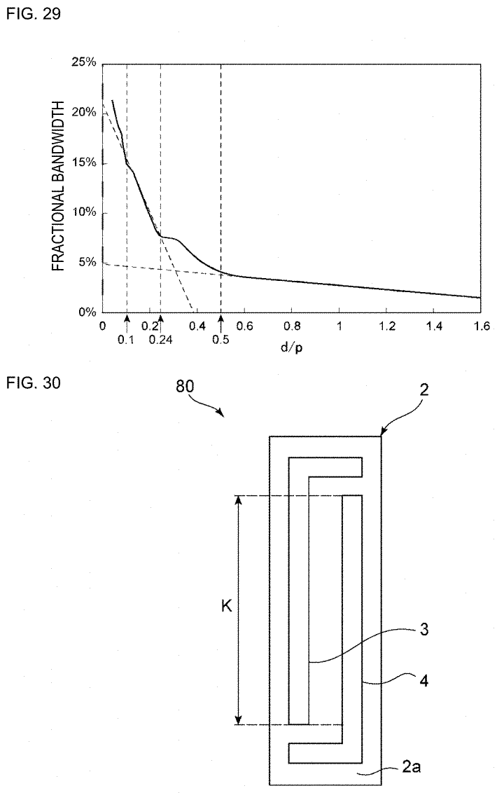

Here, when the thickness of the piezoelectric layer 2 is d and the distance between electrode centers of the electrodes 3 and 4 is p, d/p is about 0.5 or lower, and more preferably about 0.24 or lower as described above, in the present preferred embodiment. This will be described with reference to FIG. 29.

A plurality of acoustic wave devices that are the same as or similar to the acoustic wave device having the resonance characteristics illustrated in FIG. 28 were obtained, in which d/p was changed. FIG. 29 is a diagram illustrating a relationship between the d/p and fractional bandwidths of the acoustic wave devices as resonators.

As is apparent from FIG. 29, when d/p>about 0.5, the fractional bandwidth is less than about 5% even when d/p is adjusted. In contrast to this, when d/p≤about 0.5, the fractional bandwidth can be set to about 5% or greater if d/p is changed within this range, namely a resonator having a high coupling coefficient can be configured. Further, when d/p is about 0.24 or lower, the fractional bandwidth can be increased to about 7% or greater. In addition to this, if d/p is adjusted within this range, a resonator having a wider fractional bandwidth can be obtained, accordingly being able to realize a resonator having a higher coupling coefficient. Thus, it is shown that a resonator which uses bulk waves in the thickness sliding mode and has a high coupling coefficient can be configured by setting d/p to about 0.5 or lower.

FIG. 30 is a plan view of an acoustic wave device using bulk waves in the thickness sliding mode. In an acoustic wave device 80, a pair of electrodes including the electrode 3 and the electrode 4 is provided on the first main surface 2a of the piezoelectric layer 2. Here, K in FIG. 30 denotes an intersecting width. The number of pairs of electrodes may be one in the acoustic wave device of the present invention, as described above. In this configuration as well, bulk waves in the thickness sliding mode can be effectively excited when d/p is about 0.5 or lower.

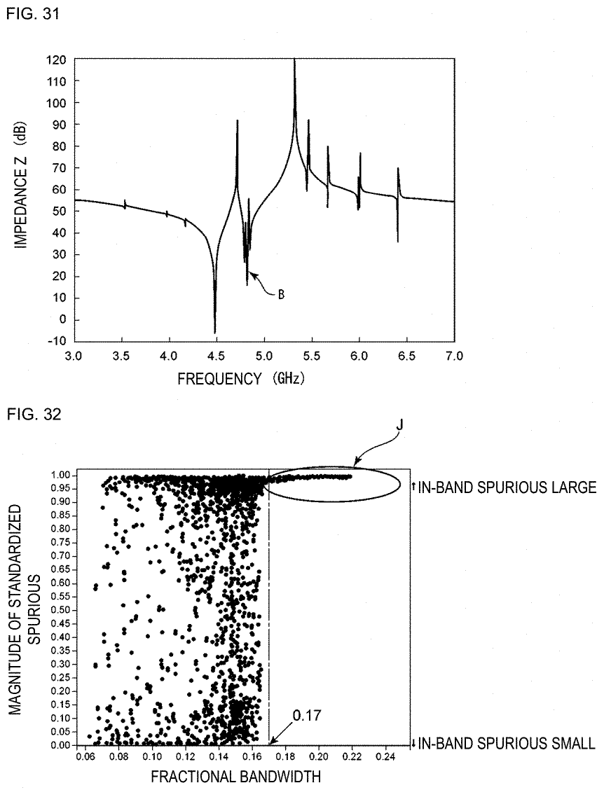

In the acoustic wave device 1, any mutually-adjacent electrodes 3 and 4 among the plurality of electrodes 3 and 4 preferably have a metallization ratio MR that satisfies MR≤1.75(d/p)+0.075, with respect to the excitation region C, which is a region in which the mutually-adjacent electrodes 3 and 4 overlap with each other when viewed in the opposing direction thereof. This configuration can effectively reduce spurious responses. This will be described with reference to FIG. 31 and FIG. 32. FIG. 31 is a reference diagram illustrating an example of resonance characteristics of the acoustic wave device 1 described above. A spurious response shown with an arrow B is seen between a resonant frequency and an anti-resonant frequency. Here, it is defined that d/p=about 0.08 and Euler angles of LiNbO₃ is (0°, 0°, 90°). Further, the metallization ratio MR mentioned above is defined as MR=about 0.35.

The metallization ratio MR will be described with reference to FIG. 24B. Focusing on one pair of electrodes 3 and 4 in the electrode structure of FIG. 24B, it is assumed that only this pair of electrodes 3 and 4 is provided. In this case, a portion enclosed by a dashed-dotted line is the excitation region C. This excitation region C is a region of the electrode 3 which overlaps with the electrode 4, a region of the electrode 4 which overlaps with the electrode 3, and a region in which the electrode 3 and the electrode 4 overlap with each other in a region between the electrode 3 and the electrode 4, when the electrode 3 and the electrode 4 are viewed in the direction orthogonal or substantially orthogonal to the longitudinal direction of the electrodes 3 and 4, that is, in the opposing direction of the same. An area of the electrodes 3 and 4 in the excitation region C with respect to an area of the excitation region C is the metallization ratio MR. Namely, the metallization ratio MR is a ratio of an area of a metallization portion with respect to the area of the excitation region C.

When a plurality of pairs of electrodes are provided, MR may be set to a rate of metallization portions included in all excitation regions with respect to a total of areas of the excitation regions.

FIG. 32 is a diagram illustrating a relationship between fractional bandwidths obtained in configuring a multitude of acoustic wave resonators and phase rotation amounts of impedance of spurious which is standardized at 180 degrees as the magnitudes of spurious responses, in accordance with the present preferred embodiment. Here, the fractional bandwidths were adjusted by variously changing the film thickness of piezoelectric layers and the dimensions of electrodes. FIG. 31 illustrates a result obtained when the piezoelectric layer made of Z-cut LiNbO₃ was used, but the same or similar tendency is obtained also when piezoelectric layers of other cut-angles are used.

A region enclosed with an ellipse J in FIG. 32 has a large spurious response which is about 1.0. Apparent from FIG. 32, when the fractional bandwidth exceeds about 0.17, that is, exceeds about 17%, a large spurious response whose spurious level is about 1 or greater appears in a pass band even when parameters constituting the fractional bandwidth are changed. In other words, a large spurious response indicated by the arrow B appears in a band as resonance characteristics illustrated in FIG. 31. Thus, the fractional bandwidth is preferably about 17% or less. In this case, a spurious response can be reduced by adjusting the film thickness of the piezoelectric layer 2 and the dimensions of the electrodes 3 and 4, for example.

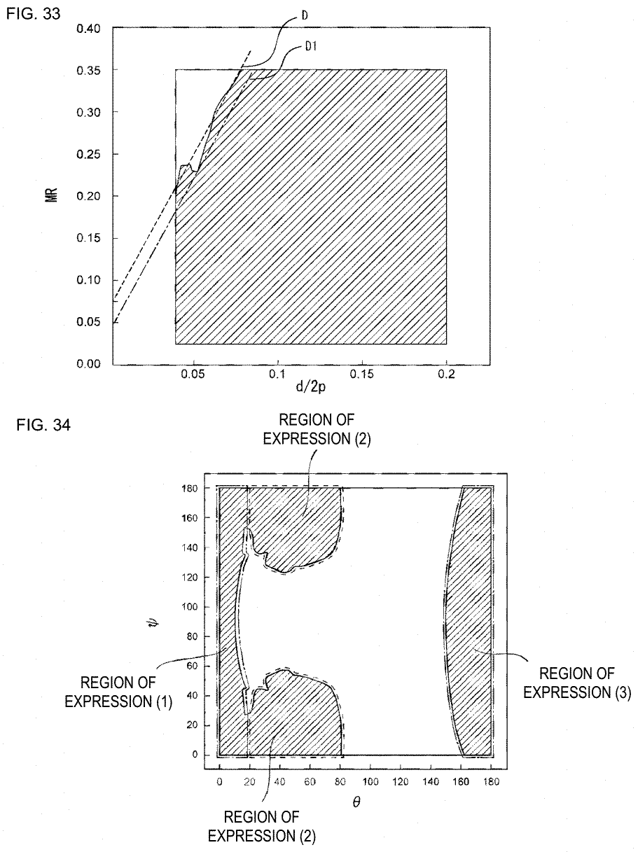

FIG. 33 is a diagram illustrating a relationship among d/2p, metallization ratio MR, and fractional bandwidth. In terms of the acoustic wave device described above, various acoustic wave devices mutually having different d/2p and MR were configured and fractional bandwidths were measured. A hatched portion on the right side of a dashed line D in FIG. 33 is a region in which the fractional bandwidth is about 17% or less. A boundary between the hatched region and a non-hatched region is expressed as MR=3.5(d/2p)+0.075. That is, MR=1.75(d/p)+0.075 is satisfied. Accordingly, MR≤1.75(d/p)+0.075 is preferably satisfied. This makes it easier to set the fractional bandwidth to about 17% or less. A region on the right side of MR=3.5(d/2p)+0.05 indicated by a dashed-dotted line D1 in FIG. 33 is more preferable. Namely, when MR≤1.75(d/p)+0.05 is satisfied, the fractional bandwidth can be securely set to about 17% or less.

FIG. 34 is a diagram showing a map of a fractional bandwidth with respect to Euler angles (0°, θ, ψ) of LiNbO₃, which is obtained by approximating d/p to 0 as much as possible. Hatched portions in FIG. 34 are regions in which a fractional bandwidth of at least about 5% or greater can be obtained, and when ranges of the regions are approximated, ranges expressed by the following Expression (1), Expression (2), and Expression (3) are obtained

(0°±10°,0° to 20°,arbitrary ψ) (1)

(0°±10°,20° to 80°,0° to 60° (1−(θ−50)²/900)^{1/2}) or (0°±10°,20° to 80°,[180°−60° (1−(θ−50)²/900)^{1/2}] to 180°) (2)

(0°±10°,[180°−30°(1−(ψ−90)²/8100)^{1/2}] to 180°,arbitrary ψ) (3)

Thus, in the Euler-angle ranges of Expression (1), Expression (2), or Expression (3) above, the fractional bandwidth can be sufficiently favorably expanded. The same applies to a configuration in which the piezoelectric layer 2 is a lithium tantalate layer.

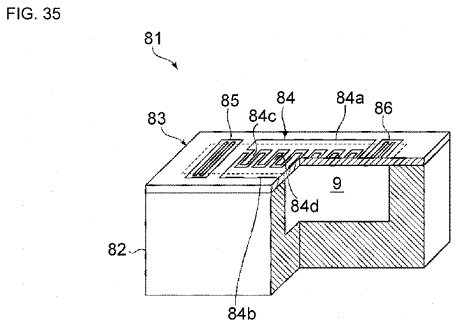

FIG. 35 is a partial cutout perspective view for explaining an acoustic wave device according to a preferred embodiment of the present invention.

An acoustic wave device 81 includes a support substrate 82. The support substrate 82 includes an open concave portion on the top surface. A piezoelectric layer 83 is laminated on the support substrate 82. Accordingly, the cavity portion 9 is provided. An IDT electrode 84 is provided on the piezoelectric layer 83 above the cavity portion 9. Reflectors 85 and 86 are provided on respective sides in an acoustic wave propagation direction of the IDT electrode 84. FIG. 35 indicates an outer circumferential edge of the cavity portion 9 with a dashed line. In this example, the IDT electrode 84 includes a first busbar 84a, a second busbar 84b, a plurality of first electrode fingers 84c, and a plurality of second electrode fingers 84d. The plurality of first electrode fingers 84c are connected to the first busbar 84a. The plurality of second electrode fingers 84d are connected to the second busbar 84b. The plurality of first electrode fingers 84c and the plurality of second electrode fingers 84d are interdigitated with each other.

In the acoustic wave device 81, Lamb waves as plate waves are excited by applying an AC electric field to the IDT electrode 84 provided above the cavity portion 9. Since the reflectors 85 and 86 are provided on the both sides, resonance characteristics based on the Lamb waves can be obtained.

Thus, an acoustic wave device according to a preferred embodiment of the present invention may use plate waves.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a support substrate;
a dielectric film on the support substrate;
a piezoelectric layer on the dielectric film; and
an excitation electrode on the piezoelectric layer; wherein
the piezoelectric layer includes a first main surface and a second main surface, the first main surface and the second main surface being opposed to each other, and the second main surface is positioned on a side including the dielectric film;
a cavity portion is provided in the dielectric film and the cavity portion overlaps with at least a portion of the excitation electrode in plan view;
the dielectric film includes a side wall surface facing the cavity portion, the side wall surface includes an inclined portion inclined so that a width of the cavity portion is decreased with increasing distance away from the piezoelectric layer, and the inclined portion includes at least an end portion, the end portion being on a side including the piezoelectric layer, in the side wall surface; and
when an angle between the inclined portion of the side wall surface and the second main surface of the piezoelectric layer is defined as an inclination angle, the inclination angle is from about 40° to about 80° inclusive.

2. The acoustic wave device according to claim 1, wherein the side wall surface includes a portion in which inclination of the side wall surface decreasing with increasing proximity to the piezoelectric layer.

3. The acoustic wave device according to claim 2, wherein the side wall surface includes a portion in which the inclination of the side wall surface changes in steps towards the piezoelectric layer.

4. The acoustic wave device according to claim 2, wherein the side wall surface includes a portion in which the inclination of the side wall surface continuously changes towards the piezoelectric layer.

5. The acoustic wave device according to claim 2, wherein the side wall surface includes a plurality of side wall portions, and inclination of at least one of the plurality of side wall portions changes at least once.

6. The acoustic wave device according to claim 5, wherein the plurality of side wall portions include a first side wall portion and a second side wall portion, and inclination of the first side wall portion does not change while inclination of the second side wall portion changes at least once.

7. The acoustic wave device according to claim 2, wherein the side wall surface includes a plurality of side wall portions each including the inclined portion, and the inclination angle differs between at least two of the inclined portions among the plurality of side wall portions.

8. The acoustic wave device according to claim 7, wherein
the piezoelectric layer includes a first direction and a second direction, the first direction and the second direction intersecting with each other, and a linear expansion coefficient in the first direction and a linear expansion coefficient in the second direction are different from each other in the piezoelectric layer; and
the plurality of side wall portions include a first side wall portion extending along the first direction and a second side wall portion extending along the second direction, and the inclination angle of the inclined portion in the first side wall portion and the inclination angle of the inclined portion in the second side wall portion are different from each other.

9. The acoustic wave device according to claim 7, wherein
the support substrate includes a third direction and a fourth direction intersecting with each other, and a linear expansion coefficient in the third direction and a linear expansion coefficient in the fourth direction are different from each other in the support substrate; and
the plurality of side wall portions include a first side wall portion extending along the third direction and a second side wall portion extending along the fourth direction, and the inclination angle of the inclined portion in the first side wall portion and the inclination angle of the inclined portion in the second side wall portion are different from each other.

10. The acoustic wave device according to claim 1, wherein the cavity portion has a rectangular or substantially rectangular shape in plan view.

11. The acoustic wave device according to claim 1, wherein the excitation electrode is an IDT electrode including a plurality of electrode fingers.

12. The acoustic wave device according to claim 11, wherein the acoustic wave device is structured to generate a plate wave.

13. The acoustic wave device according to claim 11, wherein the acoustic wave device is structured to generate a bulk wave in a thickness sliding mode.

14. The acoustic wave device according to claim 11, wherein when a thickness of the piezoelectric layer is d and a distance between centers of the electrode fingers adjacent to each other is p, d/p is about 0.5 or lower.

15. The acoustic wave device according to claim 14, wherein d/p is about 0.24 or lower.

16. The acoustic wave device according to claim 14, wherein a region in which the electrode fingers adjacent to each other overlap with each other when viewed in a direction in which the electrode fingers are opposed to each other is an excitation region, and when a metallization ratio of the plurality of electrode fingers with respect to the excitation region is MR, MR≤1.75(d/p)+0.075 is satisfied.

17. The acoustic wave device according to claim 1, wherein the piezoelectric layer is a lithium tantalate layer or a lithium niobate layer.

18. The acoustic wave device according to claim 13, wherein
the piezoelectric layer is a lithium tantalate layer or a lithium niobate layer; and
Euler angles (φ, θ, ψ) of lithium niobate or lithium tantalate constituting the piezoelectric layer are within a range of Expression (1), Expression (2), or Expression (3) below:
(0°±10°,0° to 20°,arbitrary ψ) (1);
(0°±10°,20° to 80°,0° to 60° (1−(θ−50)²/900)^{1/2}) or (0°±10°,20° to 80°,[180°−60° (1−(θ−50)²/900)^{1/2}] to 180°) (2); and
(0°±10°,[180°−30°(1−(ψ−90)²/8100)^{1/2}] to 180°,arbitrary ψ) (3)

19. The acoustic wave device according to claim 1, wherein the excitation electrode includes an upper electrode on the first main surface of the piezoelectric layer and a lower electrode on the second main surface, and the upper electrode and the lower electrode are opposed to each other with the piezoelectric layer interposed therebetween.

20. The acoustic wave device according to claim 1, wherein the support substrate is made of silicon.

21. The acoustic wave device according to claim 1, wherein the dielectric film includes at least one of silicon oxide, silicon nitride, or aluminum oxide.

22. A method for manufacturing the acoustic wave device according to claim 1, the method comprising:
forming a sacrificial layer on the piezoelectric layer;
patterning the sacrificial layer;
forming the dielectric film on the piezoelectric layer so that the dielectric film covers the sacrificial layer;
bonding the support substrate to the dielectric film;
forming the excitation electrode on the piezoelectric layer; and
removing the sacrificial layer; wherein
the sacrificial layer includes a bottom surface, the bottom surface being positioned on a side including the piezoelectric layer, and a side surface; and
when an angle between the bottom surface and the side surface of the sacrificial layer is defined as an angle β, the angle β is from about 40° to about 80° inclusive.
